(19) United States
(12) Patent Application Publication
(10) Pub. No.: US 2007/0075368 A1
(43) Pub. Date: Apr. 5, 2007

(54) CMOS inverter cell

(75) Inventors: Hyuk-Joon Kwon, Gunpo-si (KR); Sang-Woong Shin, Seongnam-si (KR)

Correspondence Address: F. CHAU & ASSOCIATES, LLC, 130 WOODBURY ROAD, WOODBURY, NY, 11797, US

(73) Assignee: Samsung Electronics Co., LTD.

(21) Appl. No.: 11/503,819

(22) Filed: Aug. 14, 2006

(30) Foreign Application Priority Data
Aug. 12, 2005 (KR) 10-2005-0074475

(51) Int. Cl. H01L 27/12; H01L 27/01; H01L 31/0392; H01L 23/48; H01L 23/52; H01L 29/40

(52) U.S. Cl. 257/347; 257/736

(57) ABSTRACT

A CMOS inverter cell having a small horizontal length which is reduced by substituting metal lines for supplying data signals to gates with a connection pattern which is mounted in one end of a supply voltage area of the CMOS inverter cell and is made of the same material as the gate. Data is supplied to the gates through at least one side of the CMOS inverter cell. A single gate pattern or a plurality of different gate patterns may be used.

### CROSS-REFERENCE TO RELATED PATENT APPLICATION

This application claims priority to Korean Patent Application No. 10-2005-0074475, filed on Aug. 12, 2005, in the Korean Intellectual Property Office, the contents of which are incorporated herein by reference.

### BACKGROUND OF THE INVENTION

1. Technical Field

The present invention relates to a layout of an inverter cell, and more particularly to a complementary metal oxide semiconductor (CMOS) inverter cell with a reduced cell area and an enhanced response speed.

2. Discussion of the Related Art

FIG. 1 illustrates the layout of a conventional CMOS inverter cell.

Referring to FIG. 1, the CMOS inverter cell 100 has a P-type MOS transistor in an upper portion and an N-type MOS transistor in a lower portion.

In the P-type MOS transistor, a left portion of a diffusion area 10 is a source terminal and a right portion of the diffusion area 10 is a drain terminal, and a P-type gate PGATE1 is disposed between the source and drain terminals. A first supply-voltage VDD is applied to the source terminal through a contact CNT, and an output signal OUTPUT is output from the drain terminal through a contact CNT. The P-type gate PGATE1 is connected to an external metal line LINE1 through a contact CNT.

In the N-type MOS transistor, a left portion of a diffusion area 11 is a source terminal and a right portion of the diffusion area 11 is a drain terminal, and an N-type gate NGATE1 is disposed between the source and drain terminals. A second supply voltage VSS is applied to the source terminal through a contact CNT and an output signal OUPUT is output from the drain terminal through a contact CNT. The N-type gate NGATE1 is connected to the external metal line LINE1 through a contact CNT.

An area AREA1 denoted by a dotted line is prepared to form the external metal line LINE1 through which signals are applied to the P-type gate PGATE1 and the N-type gate NGATE1. Since the area AREA1 extends in a horizontal direction outside an arbitrary area including the two diffusion areas 10 and 11 forming the P-type MOS transistor and the N-type MOS transistor, the area AREA1 increases the horizontal length of the cell 100.

The vertical length of the cell 100 depends on the widths of the P-type and N-type MOS transistors. When the P-type gate PGATE1 and the N-type gate NGATE1 have the same length, the current driving capability increases as the widths of the P-type and N-type gates PGAGE1 and NGATE1 increase.

FIG. 2 illustrates a layout of a conventional CMOS inverter cell.

Referring to FIG. 2, like the CMOS inverter cell 100 of FIG. 1, the CMOS inverter cell 200 has a P-type MOS transistor in an upper portion and an N-type MOS transistor in a lower portion. However, the CMOS inverter cell 200 has an external metal line LINE2 for supplying signals from an external source to a P-type gate PGATE2 of the P-type MOS transistor and an N-type gate NGATE2 of the N-type MOS transistor connected to the P-type and N-type gates PGATE2 and NGATE2 through a contact Via-CNT and to an inter-metal line LINE3, and is not directly connected to the P-type gate PGATE2 and the N-type gate NGATE2 through a contact CNT.

The horizontal length of the CMOS inverter cell 200 depends on the length of an area AREA2 denoted by a dotted line.

In the CMOS inverter cells 100 and 200 of FIGS. 1 and 2, sizable areas are used for the external metal lines LINE1 and LINE2, resulting in the overall sizes of the CMOS inverter cells 100 and 200 increasing accordingly.

To reduce the vertical length of the inverter cell, or to reduce the widths of the transistors, a finger gate structure is typically used, which results in an increase in the horizontal length of the inverter cell layout.

### SUMMARY OF THE INVENTION

According to an embodiment of the present invention, a CMOS inverter cell includes a gate pattern, a first active area pattem, a second active area pattern, a first metal line pattern, a second metal line pattern, a third metal line pattern, and a plurality of contacts in a cell boundary line. The gate pattern extends linearly and contacts a cell boundary line. The first active area pattem has a channel area overlapping the gate pattern, and a drain area and a source area disposed adjacent to the channel area. The second active area pattern has a channel area overlapping the gate pattern, and a drain area and a source area disposed adjacent to the channel area. The first metal line pattern extends substantially parallel to the gate pattern, contacts the cell boundary line, and is disposed on the first active area pattern. The second metal line pattern extends substantially parallel to the gate pattern, contacts the cell boundary line, and is disposed on the first active area pattern. The third metal line pattern extends linearly from the second metal line pattern and substantially parallel to the gate pattern, contacts the cell boundary line, and is disposed on the second active area pattern. The plurality of contacts is mounted on the drain area and the source areas of the first and second active area patterns.

The first metal line pattern connects the drain area of the first active area pattern to the drain area of the second active area pattern through the contacts mounted on the drain area of the first active area pattern and the contacts mounted on the drain area of the second active area pattern. The second metal line pattern connects the source area of the first active area pattern to a first supply voltage through the contacts mounted on the source area of the first active area pattern. The third metal line pattern connects-the source area of the second active area pattern to a second supply voltage through the contacts mounted on the source area of the second active area pattern.

According to an embodiment of the present invention, a CMOS inverter cell includes a first gate pattern, a second gate pattern, an internal connection pattern, a first active area pattern, a second active area pattern, a first metal line pattern, a second metal line pattern, a third metal line pattern, and a plurality of contacts in a cell boundary line.

The internal connection pattern connects the first gate pattern to the second gate pattern. The first active area pattern has a channel area overlapping the first gate pattern, and a drain area and a source area disposed adjacent to the channel area. The second.active, area pattern has a channel area overlapping the second gate pattern, and a drain area and a source area disposed adjacent to the channel area. The first metal line pattern extends substantially parallel to the first gate pattern and the second gate pattern, contacts a cell boundary line, and is disposed on the first active area pattern. The second metal line pattern extends substantially parallel to the first gate pattern, contacts the cell boundary line, and is disposed on the first active area pattern. The third metal line pattern extends linearly from the second metal line pattern and substantially parallel to the second gate pattern, contacts the cell boundary line, and is disposed on the second active area pattern. The plurality of contacts is mounted on the gate pattern, and the drain and source areas of the first and second active area patterns.

The first metal line pattern connects the drain area of the first active area pattern to the drain area of the second active area pattern through the contacts mounted on the drain area of the first active area pattern and the contacts mounted on the-drain area of the second active area pattern. The second metal line pattern connects the source area of the first active area pattern to a first supply voltage through the contacts mounted on the source area of the first active area pattern. The third metal line pattern connects the source area of the second active area pattern to a second supply voltage through the contacts mounted on the source area of the second active area pattern. The internal connection pattern connects the first gate pattern to the second gate pattern through the contacts mounted on the first and second gate patterns.

### BRIEF DESCRIPTION OF THE DRAWINGS

Exemplary embodiments of the present invention can be understood in more detail from the following descriptions taken in conjunction with the attached drawings in which:

FIG. 1 illustrates a layout of a conventional CMOS inverter cell;

FIG. 2 illustrates a layout of a conventional CMOS inverter cell;

FIG. 3 illustrates a layout of a CMOS inverter cell according to an embodiment of the present invention;

FIG. 4 illustrates a layout of a CMOS inverter cell according to an embodiment of the present invention;

FIG. 5 illustrates a layout of a CMOS inverter cell according to an embodiment of the present invention;

FIG. 6 illustrates a layout of a CMOS inverter cell according to an embodiment of the present invention;

FIG. 7 illustrates a layout of a CMOS inverter cell according to an embodiment of the present invention; and

FIG. 8 illustrates a layout of a CMOS inverter cell according to an embodiment of the present invention.

### DETAILED DESCRIPTION OF EXEMPLARY EMBODIMENTS

The present invention will now be described more fully with reference to the accompanying drawings, in which exemplary embodiments of the invention are shown. Like reference numbers refer to like components throughout the drawings.

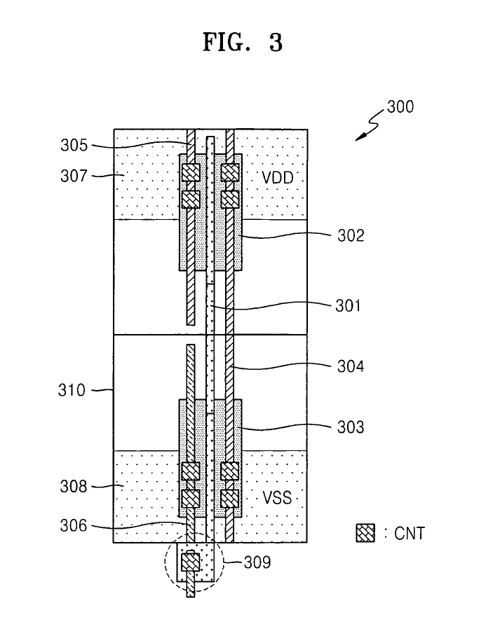

FIG. 3 illustrates a layout of a CMOS inverter cell according to an embodiment of the present invention.

Referring to FIG. 3, the CMOS inverter cell 300 includes a gate pattern 301, a first active area pattern 302, a second active area pattern 303, a first metal line pattern 304, a second metal line pattern 305, a third metal line pattern 306, a first supply voltage line 307, a second supply voltage line 308, a gate connection pattern 309, and a plurality of contacts CNT.

The gate pattern 301 contacts one side of a cell boundary line 310 and extends in substantially a straight line. The first active area pattern 302 is an active area of a P-type MOS transistor including a channel area overlapping the gate pattern 301, and a drain area and a source area disposed at either side of the channel area. The second active area pattern 303 is an active area of an N-type MOS transistor including a channel area overlapping the gate pattern 301, and a drain area and a source area disposed at either side of the channel area.

Contacts CNT are respectively disposed in upper portions of the drain and source areas of the first and second active area patterns 302 and 303. One end of the first metal line pattern 304 contacts one side of the cell boundary line 310. The first metal line pattern 304 extends substantially parallel to the gate pattern 301 and transmits an output signal of the inverter cell 300. The second metal line pattern 305 extends substantially parallel to the gate pattern 301, and one end of the second metal line pattern 305 contacts one side of the cell boundary line 310. The second and third metal lines 305 and 306 extend substantially along the same line. The third metal line 306 extends substantially parallel to the gate pattern 301, and one end of the third metal line 306 contacts the cell boundary line 310.

The first metal line pattern 304 connects the drain area of the first active area pattern 302 to the drain area of the second active area pattern 303 through one of the contacts CNT mounted on the upper surface of the drain area of the first active area pattern 302 and one of the contacts CNT mounted on the upper surface of the drain area of the second active area pattern 303. The second metal line pattern 305 connects the source area of the first active area pattern 302 to a first supply voltage VDD through one of the contacts CNT mounted on the source area of the first active area pattern 302. The third metal line pattem 306 connects the source area of the second active area pattern 303 to a second supply voltage VSS through one of the contacts CNT mounted on the source area of the second active area pattern 303.

To supply a signal to the gate pattern 301, the gate connection pattern 309 is formed outside the cell boundary line 310. In FIG. 3, the gate connection pattern 309 contacts a portion of the cell boundary line 310 where the N-type MOS transistor is disposed.

The first supply voltage VDD may be supplied through the first supply voltage line 307 and the second supply voltage VSS may be supplied through the second supply voltage line 308. The gate connection pattern 309 is made of the same material as the gate pattern 301. The gate connection pattern 309 is formed outside and contacts the cell boundary line 310, and transmits signals to the gate pattern 301.

FIG. 3 illustrates a case where the gate connection pattern 309 contacts the cell boundary line 310 where the N-type MOS transistor is disposed.

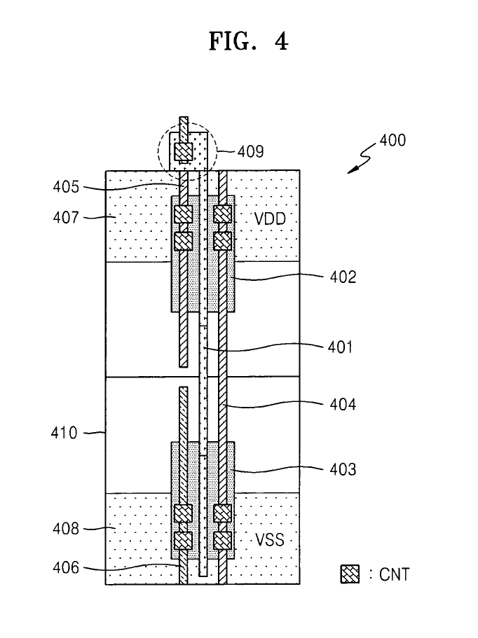

FIG. 4 illustrates a layout of a CMOS inverter cell according to an embodiment of the present invention.

The CMOS inverter cell 400 illustrated in FIG. 4 is similar to the CMOS inverter cell 300 of FIG. 3. A gate connection pattern 409 contacts a portion of a cell boundary line 410 where a P-type MOS transistor is disposed.

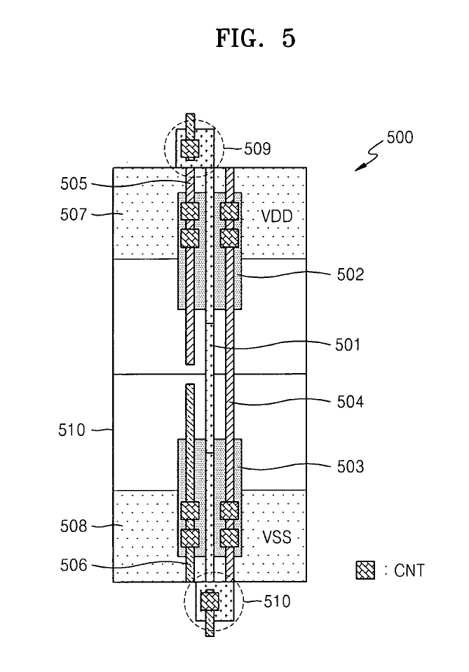

FIG. 5 illustrates a layout of a CMOS inverter cell according to an embodiment of the present invention.

The CMOS inverter cell 500 illustrated in FIG. 5 is similar to the CMOS inverter cell of FIG. 4. Two gate connection patterns 509 and 510 contact portions of cell boundary lines 510 where a P-type MOS transistor and an N-type MOS transistor are disposed.

Referring to FIGS. 3, 4, and 5, in the CMOS inverter cells 300, 400 and 500, a single gate pattern 301, 401, and 501, respectively, is used as a gate terminal of a P-type MOS transistor and an N-type MOS transistor. Also, the arrangement and number of the gate connection patterns 309, 409, 509, and 510 for respectively supplying signals to the gate patterns 301, 401, and 501 can vary. Accordingly, in the CMOS inverter cell according to embodiments of the present invention, data can be transmitted to a gate pattern through one side of the cell, or data can be transmitted to a gate pattern through both sides of the cell.

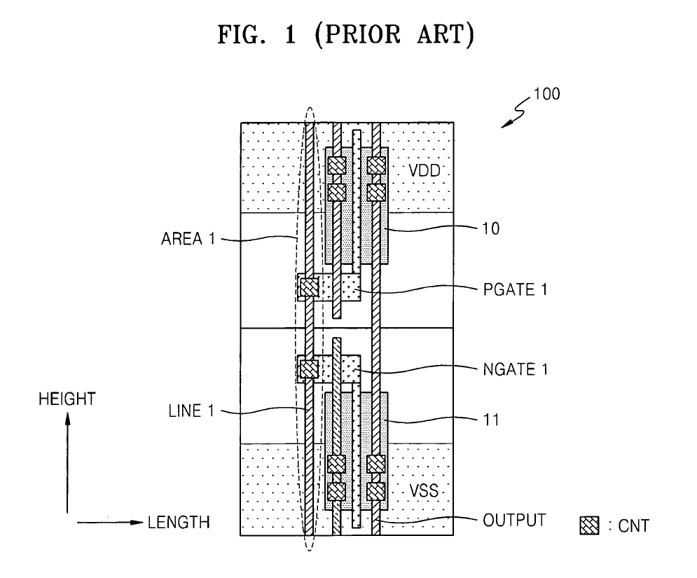

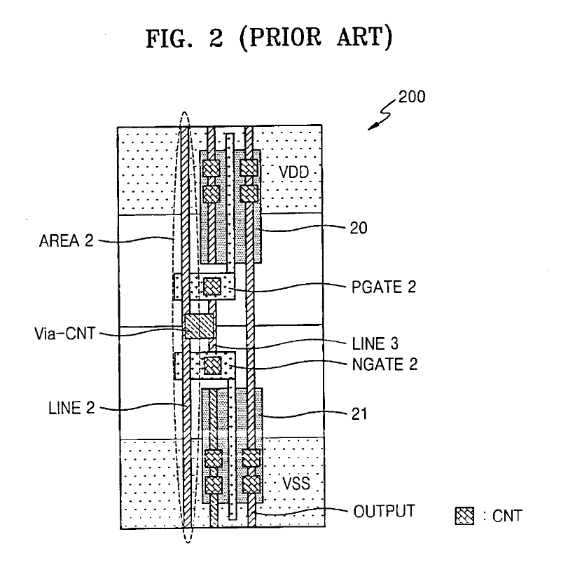

The predetermined areas AREA1 and AREA2 for the external metal lines LINE1 and LINE2 of the conventional inverter cells 100 and 200 as illustrated in FIGS. 1 and 2 are not needed in the CMOS inverter cells 300, 400 and 500 according to embodiments of the present invention as illustrated in FIGS. 3, 4, and 5.

CMOS inverter cells according to embodiments of the present invention have a gate pattern of a P-type MOS transistor and a gate pattern of an N-type MOS transistor connected through, for example, a metal line. The gate pattern of the P-type MOS transistor and the gate pattern of the N-type MOS transistor are made of different materials so threshold voltages can be independently adjusted.

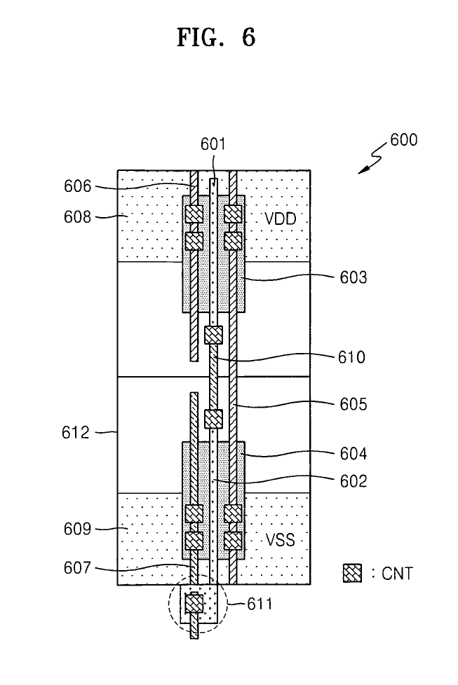

FIG. 6 illustrates a layout of a CMOS inverter cell according to an embodiment of the present invention.

Referring to FIG. 6, the CMOS inverter cell 600 includes a first gate pattern 601, a second gate pattern 602, a first active area pattern 603, a second active area pattern 604, a first metal line pattern 605, a second metal line pattern 606, a third metal line pattern 607, a first supply voltage line 608, a second supply voltage line 609, a connection pattern 610, and a plurality of contacts CNT.

The first gate pattern 601 and the second gate pattern 602 may be made of poly silicon. The first gate pattern 601 and the second gate pattern 602 are electrically connected to each other via the connection pattern 610 through the contacts CNT. Here, the contacts CNT disposed between the first gate pattern 601 and the internal connection pattern 610 and between the second gate pattern 602 and the internal connection pattern 610 may be in the same layer as contacts CNT mounted on source and drain areas or may in different layers than the contacts CNT mounted on the source and drain areas.

The first active area pattern 603 is an active area of a P-type MOS transistor including a channel area overlapping the first gate pattern 601, and a drain area and a source area disposed at either side of the channel area. The second active area pattern 604 is an active area of an N-type MOS transistor including a channel area overlapping the second gate pattern 602, and a drain area and a source area disposed at either side of the channel area. The contacts CNT are mounted on the source areas and drain areas of the first active area pattern 603 and the second active area pattern 604.

The first metal line pattern 605 extends substantially parallel to the first gate pattern 601 and contacts a cell boundary line 612. The second metal line pattern 606 extends substantially parallel to the second gate pattern 602 and contacts the cell boundary line 612. The third metal line pattern 607 extends along the same line as the second metal line pattern 606, extends substantially parallel to the first gate pattern 601 and the second gate pattern 602, and contacts the cell boundary line 612. The first metal line pattern 605 connects the drain area of the first active area pattern 603 with the drain area of the second active area pattern 604 through one of the contacts CNT mounted on the drain area of the first active area pattern 603 and one of the contacts CNT mounted on the drain area of the second active area pattern 604. The second metal line pattern 606 connects the source area of the first active area pattern 603 to a first supply voltage VDD through one of the contacts CNT mounted on the source area of the first active area pattern 603. The third metal line pattern 607 connects the source area of the second active area pattern 604 to a second supply voltage VSS through one of the contacts CNT mounted on the source area of the second active area pattern 604.

To supply signals to the second gate pattern 602, a gate connection pattern 611 is mounted outside the boundary line 612. In FIG. 6, the gate connection pattern 611 contacts a portion of the cell boundary line 612 where the N-type MOS transistor is formed.

The first supply voltage VDD may be applied through the first supply voltage line 608 and the second supply voltage VSS may be applied through the second supply voltage line 609. The connection pattern 610 connects the first gate pattern 601 to the second gate pattern 602. The connection pattern 610 may be made of the same material as the first and second gate patterns 601 and 602 or may be formed as a metal line.

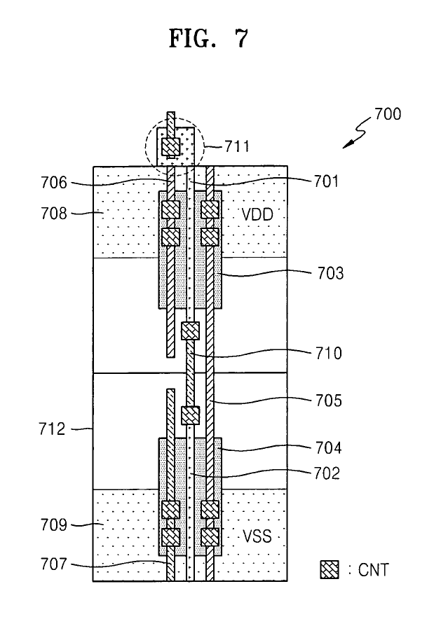

FIG. 7 illustrates a layout of a CMOS inverter cell according to an embodiment of the present invention. The CMOS inverter cell 700 illustrated in FIG. 7 is similar to the CMOS inverter cell 600 of FIG. 6. A gate connection pattern 711 contacts a portion of a cell boundary line 712 where a P-type MOS transistor is disposed.

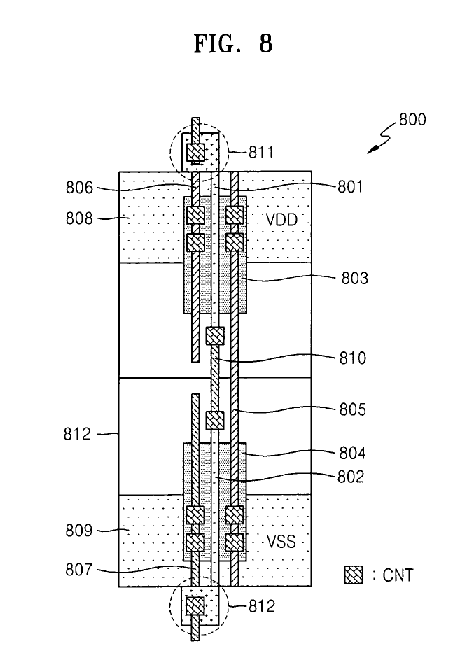

FIG. 8 illustrates a layout of a CMOS inverter cell according to an embodiment of the present invention. The CMOS inverter cell 800 illustrated in FIG. 8 is similar to the CMOS inverter cells 600 and 700 of FIGS. 6 and 7. Two gate connection patterns 811 and 812 contact portions of cell boundary lines where a P-type MOS transistor and an N-type MOS transistor are disposed.

Referring to FIGS. 6, 7, and 8, in the CMOS inverter cells 600, 700, and 800, a pair of gate patterns 601 and 602, 701 and 702, and 801 and 802, respectively, which are separated from each other, are used as gate terminals of a P-type MOS transistor and an N-type MOS transistor. Also, the CMOS inverter cells 600, 700, and 800 further include internal connection patterns 610, 710, and 810 for connecting the gate pattern pairs 601 and 602, 701 and 702, and 801 and 802.

Accordingly, data can be transmitted to a gate pattern through one side of the CMOS inverter cells 600, 700, and 800 or through both sides of the CMOS inverter cells 600, 700, and 800.

The predetermined areas AREA1 and AREA2 for the external metal lines LINE1 and LINE2 of the conventional CMOS inverter cells 100 and 200 as illustrated in FIGS. 1 and 2 are not needed in the CMOS inverter cells 600, 700, and 800 according to embodiments of the present invention as illustrated in FIGS. 6, 7, and 8.

The CMOS inverter cells 300, 400, 500, 600, 700, and 800 according to embodiments of the present invention as illustrated in FIGS. 3 through 8 have a smaller horizontal length than the conventional CMOS inverter cells 100 and 200 as illustrated in FIGS. 1 and 2, while providing the same driving capability and a smaller size.

To implement a CMOS inverter cell having greater driving capability than a conventional CMOS inverter cell, a finger gate structure can be adopted into a small-sized CMOS inverter cell according to an embodiment of the present invention. Accordingly, it is possible to improve the driving capability of a CMOS inverter cell while maintaining the size of a conventional CMOS inverter cell.

Since a CMOS inverter cell according to embodiments of the present invention is smaller than a conventional inverter cell having the same driving capability, parasitic resistance and parasitic capacitance of the entire circuit is reduced.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A CMOS inverter cell, comprising:
a gate pattern extending linearly and contacting a cell boundary line;
a first active area pattern having a channel area overlapping the gate pattern, and a drain area and a source area disposed adjacent to the channel area;
a second active area pattern having a channel area overlapping the gate pattern, and a drain area and a source area disposed adjacent to the channel area;
a first metal line pattern that extends substantially parallel to the gate pattern, contacts the cell boundary line, and is disposed on the first active area pattern;
a second metal line pattern that extends substantially parallel to the gate pattern, contacts the cell boundary line, and is disposed on the first active area pattern;
a third metal line pattern that extends linearly from the second metal line pattern and substantially parallel to the gate pattern, contacts the cell boundary line, and is disposed on the second active area pattern; and
a plurality of contacts mounted on the drain and source areas of the first and second active area patterns,
wherein the first metal line pattern connects the drain area of the first active area pattern to the drain area of the second active area pattern through the contacts mounted on the drain area of the first active area pattern and the contacts mounted on the drain area of the second active area pattern,
the second metal line pattern connects the source area of the first active area pattern to a first supply voltage through the contacts mounted on the source area of the first active area pattern, and
the third metal line pattern connects the source area of the second active area pattern to a second supply voltage through the contacts mounted on the source area of the second active area pattern.

2. The CMOS inverter cell of claim 1, further comprising:
a gate connection pattern that contacts the cell boundary line, is made of the same material as the gate pattern and is connected to the gate pattern.

3. The CMOS inverter cell of claim 2, wherein the gate connection pattern contacts the cell boundary line adjacent to the first active area pattern or the second active area pattern.

4. The CMOS inverter cell of claim 2, wherein the gate connection pattern contacts the cell boundary line adjacent to the first active area pattern and the second active area pattern.

5. The CMOS inverter cell of claim 1, wherein the channel area, the drain area, and the source area of the first active area pattern respectively correspond to a channel area, a drain area, and a source area of a P-type MOS transistor, and
the channel area, the drain area, and the source area of the second active area pattern respectively correspond to a channel area, a drain area, and a source area of an N-type MOS transistor.

6. The CMOS inverter cell of claim 1, wherein the first supply voltage is higher than the second supply voltage.

7. The CMOS inverter cell of claim 1, further comprising:
a first supply voltage line pattern overlapping the source area of the first active area pattern and applying the first supply voltage; and
a second supply voltage line pattern overlapping the source area of the second active area pattern and applying the second supply voltage,
wherein the first supply voltage pattern is connected to the source area of the first active area pattern through the contacts mounted on the source area of the first active area pattern, and the second supply line pattern is connected to the source area of the second active area pattern through the contacts mounted on the source area of the second active area pattern, and
the first supply voltage is higher than the second supply voltage.

8. The CMOS inverter cell of claim 7, wherein the first supply voltage line pattern and the second supply voltage line pattern extend substantially parallel to the gate pattern, the first metal line pattern, the second metal line pattern, and the third metal line pattern.

9. A CMOS inverter cell, comprising:
a first gate pattern;
a second gate pattern;
an internal connection pattern connecting the first gate pattern to the second gate pattern;
a first active area pattern having a channel area overlapping the first gate pattern, and a drain area and a source area disposed adjacent to the channel area;
a second active area pattern having a channel area overlapping the second gate pattern, and a drain area and a source area disposed adjacent to the channel area;
a first metal line pattern that extends substantially parallel to the first gate pattern and the second gate pattern, contacts a cell boundary line, and is disposed on the first active area pattern;
a second metal line pattern that extends substantially parallel to the first gate pattern, contacts the cell boundary line, and is disposed on the first active area pattern;
a third metal line pattern that extends linearly from the second metal line pattern and substantially parallel to the second gate pattern, contacts the cell boundary line, and is disposed on the second active area pattern; and
a plurality of contacts mounted on the gate pattern, and the drain and source areas of the first and second active area patterns,
wherein the first metal line pattern connects the drain area of the first active area pattern to the drain area of the second active area pattern through the contacts mounted on the drain area of the first active area pattern and the contacts mounted on the drain area of the second active area pattern,
the second metal line pattern connects the source area of the first active area pattern to a first supply voltage through the contacts mounted on the source area of the first active area pattern,
the third metal line pattern connects the source area of the second active area pattern with a second supply voltage through the contacts mounted on the source area of the second active area pattern, and
the internal connection pattern connects the first gate pattern to the second gate pattern through the contacts mounted on the first and second gate patterns.

10. The CMOS inverter cell of claim 9, wherein the internal connection pattern, the first gate pattern, and the second gate pattern are made of the same material.

11. The CMOS inverter cell of claim 10, wherein the first and second gate patterns are made of polysilicon and the internal connection pattern is made of metal.

12. The CMOS inverter cell of claim 9, further comprising:
a gate connection pattern disposed outside the cell boundary line and made of the same material as the first and second gate patterns,
wherein one of the first and second gate patterns is connected to the gate connection pattern.

13. The CMOS inverter cell of claim 12, wherein the gate connection pattern contacts the cell boundary line adjacent to the first active area pattern or the second active area pattern.

14. The CMOS inverter cell of claim 12, wherein the gate connection pattern is connected to the first and second gate patterns and contacts the cell boundary line adjacent to the first active area pattern and the second active area pattern.

15. The CMOS inverter cell of claim 9, wherein the channel area, the drain area, and the source area of the first active area pattern respectively correspond to a channel area, a drain area, and a source area of a P-type MOS transistor, and
the channel area, the drain area, and the source area of the second active area pattern respectively correspond to a channel area, a drain area, and a source area of an N-type MOS transistor.

16. The CMOS inverter cell of claim 9, wherein the first supply voltage is higher than the second supply voltage.

17. The CMOS inverter cell of claim 9, further comprising:
a first supply voltage line pattern overlapping the source area of the first active area pattern and applying the first supply voltage; and
a second supply voltage line pattern overlapping the source area of the second active area pattern and applying the second supply voltage,
wherein the first supply voltage line pattern is connected to the source area of the first active area pattern through the contacts mounted on the source area of the first active area pattern, and the second supply voltage line pattern is connected to the source area of the second active area pattern through the contacts mounted on the source area of the second active area pattern, and
the first supply voltage is higher than the second supply voltage.

18. The CMOS inverter cell of claim 17, wherein lines extending from the first supply voltage line pattern and the second supply voltage line pattern intersect lines extending from the gate pattern, the first metal line pattern, the second metal line pattern, and the third metal line pattern.
